(19) United States
(12) Patent Application Publication
(10) Pub. No.: US 2001/0028256 A1
(43) Pub. Date: Oct. 11, 2001

(54) Diagnostic apparatus for electronics circuit and diagnostic method using same

(76) Inventor: Mishio Hayashi, Saitama-ken (JP)

Correspondence Address: MURAMATSU & ASSOCIATES, Suite 225, 7700 Irvine Center Drive, Irvine, CA, 92618, US

(21) Appl. No.: 09/746,082

(22) Filed: Dec. 21, 2000

(30) Foreign Application Priority Data
Dec. 21, 1999 (JP) 11-362748

(51) Int. Cl. G01R 31/26

(52) U.S. Cl. 324/765

(57) ABSTRACT

A diagnostic apparatus for detecting failure points in an electronic circuit through a non-contact fashion. The diagnostic apparatus includes means for applying a diagnostic support program to activate components in the electronic circuit under test, a detector array for detecting voltage signals representing electric fields of various locations in the electronic circuit under test, a measurement unit for converting the voltage signals to measured data representing negative peak rates Mₚᵣ, a processing unit for determining defective points in the electronic circuit under test based on measured data representing the negative peak rates Mₚᵣ and supplemental information in data bases produced in advance, and a display for displaying the defective points specified by the processing unit.

### FIELD OF THE INVENTION

This invention relates to an apparatus and method for diagnosing or testing electronic circuits such as a printed circuit board or IC chip mounting a large number of electrical components, and more particularly, to an apparatus and method for diagnosing or testing electronic circuits in a non-contact fashion to specify defective locations of the electronic circuits with use of characteristics where mark rates of signals in such defective locations change.

### BACKGROUND OF THE INVENTION

An example of apparatus that diagnoses an electronic circuit network by a non-contact method is described in the Japanese Laid-Open Publication No. 8-146101 (Japanese Patent Application No. 6-314193), titled “Visual Analytical Apparatus Of Printed Circuit Board Operations”, filed and owned by an assignee of this invention. As another example is disclosed in the Japanese Utility Model Application No. 5-72797, titled “Non-Contact Probe Used in Apparatus for Detecting Abnormalities in Printed Circuit Board”.

In this invention, the conventional technology is described based on the Japanese Laid-Open Publication No. 8-146101. The apparatus in the conventional technology is a diagnostic apparatus which accounts for the following functions. In an electronics circuit such as a logic circuit in a printed circuit board that performs periodical operations, a mark rate Mr will change when there is a defect on a circuit layout pattern or a land in the circuit. Here, a mark rate is a ratio of generation between high levels and low levels of a signal. Namely, a layout pattern or a land that changes the mark rate is detected by a detector unit having a large number of detector electrodes which is pressed against the circuit under test. The value of the detected mark rate Mᵣ is then compared with a mark rate of a non-defective circuit of the same lay out, thereby determining whether the operation of the particular layout pattern or land in the printed circuit board (electronic circuit under test) is defective or not.

A further explanation regarding the mark rate Mᵣ is given hereafter. A low-level period of the signal detected by the detector electrodes is denoted by T_{low}, a high-level period of the detected signal is denoted by Tₕᵢ, and a negative amplitude of the signal is denoted by V₋ₚ (>0), and a positive amplitude of the signal is denoted by V₊ₚ (>0). Then, the mark rate Mᵣ will become T_{low}×V₋ₚ=Tₕᵢ×V₊ₚ because the detected signal maintains its periodic nature, and it will stabilize with the relationship of T_{low}=Tₕᵢ (V_{+p/V}₋ₚ). Meanwhile, the mark rate Mᵣ of the detected signal is expressed as Mᵣ=Tₕᵢ/(Tₕᵢ+T_{low}), and thus, by applying the mark rate Mᵣ, the above equation becomes:

Mᵣ=Tₕᵢ/{Tₕᵢ+Tₕᵢ×(V₊ₚ/V₋ₚ)}−V₋ₚ/(V₋ₚ+V₋ₚ)

From this, the mark rate Mᵣ is determined if both the positive and negative peak voltages of the measuring point (circuit pattern or land of a printed circuit board or IC chip) can be measured. Even though coupling capacitance of the detector electrode changes, since both the negative and positive peak voltages V₊ₚ and V₋ₚ of the detected signal also change accordingly, the result from the above equation will not be affected because such changes are equal to both peak voltages. The mark rate Mᵣ, therefore, are not affected by the values of the coupling capacitance.

In the event that the value of the mark rate Mᵣ obtained in the above noted relationship is different from that of the non-defective electronic circuit, i.e., a reference circuit, the operation at the measured circuit pattern in the printed circuit board will then be judged as defective.

The detector electrodes are arranged in a matrix manner in the detector unit which is typically an insulation sheet. When the detector unit is positioned, for example on the printed circuit board to be diagnosed, the detector electrodes are optionally placed regardless of the lands and pattern positions of the electronics circuit on the printed circuit board. This will sometimes cause that each electrode detects two or more signals in each block, which are then superimposed together in a certain ratio. However, the resultant signal is not a true logic signal in the meaning of the standard two-valued logic, and thus a resultant mark rate cannot be considered as the conventional “mark rate Mᵣ”.

Therefore, in the present invention, the ratio of generation between the low level voltages and high level voltages in the detected signal is defined as a “negative peak rate Mₚᵣ” instead. The negative peak rate Mₚᵣ is a numeric value defined by positive peak voltage signals V₊ₚ (>0), and negative peak voltage signals V₋ₚ (>0), which is Mₚᵣ=V₋ₚ/(V₊ₚ+V₋ₚ). Therefore, if the detected signal does not include the superimposed signals, then the negative peak rate Mₚᵣ of the present invention will be identical to the conventional mark rate Mᵣ.

FIG. 6 is a block diagram that demonstrates an example of diagnostic apparatus described in the Japanese Patent Laid-Open Publication No. 8-146101 noted above. In this example, the diagnostic apparatus is composed of a detector array 50, a measurement unit 60, a switch array 70, a processing unit 72, and a display 74.

The detector array 50 has a configuration integrated by detector electrodes 21ₐₐ-21ₙₘ and a detector sheet 22. The detector electrodes are independent from one another and laid out flatly in a matrix manner of N rows and M columns, and the detector sheet 22 is a sheet of insulating material with elasticity. The detector array 50 is placed on the electronics circuit to be tested, such as a printed circuit board. Electric signal detection is made by each detector electrode 21ᵢⱼ (i=a−n, j=a−m) through capacitive coupling between the detector electrode 21ᵢⱼ and a conductive material, such as a circuit pattern in the printed circuit board immediately below the detector electrode 21ᵢⱼ,i.e., a detection area.

In such a diagnostic process, the entire sheet of the detector array 50, is placed on the printed circuit board under test without regard to specific positions of conductor (circuit patterns or lands) on the printed circuit board. The detector electrodes 21ₐₐ−21ₙₘ are aligned in the matrix manner as noted above with the same pitch throughout. Thus, the detector electrode 21ᵢ may have, under its detection area, only one circuit pattern, or two or more circuit patterns, or no circuit pattern at all. Even in this condition, except for the case of the no conductive circuit pattern, a negative peak rate Mₚᵣ=V₋ₚ/(V₊ₚ+V₋ₚ) still exists and can be measured by this diagnostic apparatus.

The measurement unit 60 is established by arranging negative peak rate measurement elements 60ₐₐ−60ₙₘ in the matrix manner of N rows and M columns right near the corresponding detector electrodes 20ₐₐ−20ₙₘ of the detector array 50. Each negative peak rate measurement element 60ᵢⱼ is constructed with an input buffer 61a, a positive peak voltage detector 63a, a negative peak voltage detector 64a, subtraction unit (subtractor) 65a, an inverter 66a, and a divider 67a. This arrangement in the negative peak rate measurement element 60 calculates the negative peak rate Mₚᵣ of the input signal from the detector electrodes 21 based on the relationship of Mₚᵣ=Vₚ/(Vₚ+Vₚ) and outputs a signal voltage which is proportional to the negative peak rate Mₚᵣ.

The input buffer 61a is an impedance conversion circuit with low input capacitance and high input impedance, and is comprised, for example of a FET (field effect transistor). The positive peak voltage detector 63a detects a positive peak voltage level V₊ₚ of the input signal, and the negative peak voltage detector 64a detects a negative peak voltage level −V₋ₚ of the input signal. The subtraction unit (subtractor) 65a obtains a peak-to-peak voltage between the positive peak voltage level V₊ₚ and the negative peak voltage level −V₋ₚ from the voltage detectors 63a and 64a. Because the negative peak voltage −V₋ₚ has a negative polarity, the substraction unit 65a adds the negative and positive voltages and provides the result to an input terminal of the divider 67a as a denominator.

The inverter 66a inverts the polarity of the negative peak voltage level −V₋ₚ received from the negative peak voltage detector 64a to a positive voltage, and supplies the positive voltage value to another input terminal of the divider 67a as a numerator. The divider 67 performs the division between the data from the two input terminals and thus calculates the negative peak rate Mₚᵣ=V₋ₚ/(V₊ₚ+V₋ₚ) of the input signal. The divider 67a provides the negative peak rate Mₚᵣ to the switch array 70. The subtraction unit 65a and the divider 67a are formed, for example, with analog arithmetic circuits.

The switch array 70 has an array of switches therein. The switch array 70 receives a voltage that corresponds to the negative peak rate Mₚᵣ from each of the negative peak measurement element 60ᵢⱼ, and transmits the voltage to the processing unit 72 by sequentially switching the array of switches. Upon receiving the voltages indicating the negative peak rates Mₚᵣ from the switch array 70, the processing unit 72 converts the analog voltages to digital signals. The processing unit 72 transmits the resultant data to the display 74 where the measured negative peak rates are displayed by color or by numerical data or the like.

In the foregoing explanation, the analog voltage corresponding to each negative peak rate Mₚᵣ from the measurement unit 60 is received and sequentially switched over by the switch array 70. The analog voltage is converted to the digital signal by the processing unit 72, and the resultant negative peak rates are displayed on the display 74 with color or other types of data.

In the other example, although not shown in the drawings, the analog voltage from the measurement unit 60 corresponding to the negative peak rate Mₚᵣ is directly transmitted to a color display of M×N color elements. The color elements are arranged in the positions corresponding to the detector electrodes 21ₐₐ−21ₙₘ in the detector array 50, thereby displaying the negative peak rates Mₚᵣ of the printed circuit board under test with colors in the image of the measured positions on the board.

The conventional technology described above provides a practical and convenient way of diagnosing the electronic circuit with non-contact manner. However, this conventional apparatus requires an electric circuit to be tested which has a logic circuit that periodically operates. Generally, in the normal state of operating in the electric circuit, a rate of operation in the electric circuit (hereafter referred to as “activation rate” of the circuit) is lower than 50%. Therefore, even if the operation of the entire board can be observed at the same time by this conventional technology, a diagnostic rate of greater than 50% cannot be achieved.

The conventional diagnosing apparatus is supposedly able to detect, not only pass/fail of the printed circuit board under test, but also specify the failure points or defective locations of the printed circuit board under test. However, generally, operations in the electric circuit in the printed circuit board are correlated with one another. Thus, if a certain point of the electric circuit is defective, other circuits such as the circuits in the later stages will be affected by the defect, resulting in changes in the negative peak rates Mₚᵣ. Therefore, it is not possible to obtain an accurate diagnostic result for each unit of circuit pattern or node, but rather, the diagnostic result can be obtained for an area associated with multiple patterns or nodes. In other words, the conventional technology is not capable of specifying the defective point or location in the printed circuit board. As a consequence, a separate diagnosing procedure or manual inspection will be required in order to determine the defective point in the printed circuit board under test.

Furthermore, because of the increasing circuit density and miniaturization in recent electronics components as well as high functionality in integrated circuits, the complexity of the printed circuit board under test per unit area has been increasing. As a consequence, detection of defective locations in the circuit board and repair operations for such defects have become more and more complicated and time consuming.

### SUMMARY OF THE INVENTION

Based on the foregoing, it is an object of the present invention to provide a diagnostic apparatus and method for detecting failure points in a printed circuit board or an LSI through a non-contact fashion.

It is another object of the present invention to provide a diagnostic apparatus and method for testing an electronic circuit network which is capable of effectively measuring a negative peak rate and specifying a location of a failure point in the electronic circuit network.

It is a further object of the present invention to provide a diagnostic apparatus and method detecting failure modes in the electronic circuit network under test by evaluating similarity between measured data and data base prepared in advance.

In order to achieve the above goals, an electronic circuit network diagnostic apparatus of the present invention improves the conventional example of FIG. 6, especially the processing unit thereof. Namely, a processing unit in the diagnostic apparatus of the present invention includes an analog-to-digital (AD) converter, arithmetic controller, a memory, and a supplemental information input unit.

Electronic circuit networks which are suitable for being tested by the diagnostic apparatus of the present invention are printed circuit boards or LSIs having a CPU (central processing unit) which is capable of rewriting programs. Here, the CPU includes a MPU (micro-processor unit) and a DSP (digital signal processor). Most of the printed circuit boards that are currently in use have at least one of such controllers therein, and thus most of the printed circuit boards can be tested by the diagnostic apparatus of the present invention.

In the present invention, a “diagnostic support program” is prepared prior to the start of the diagnosing operation and is installed in the CPU. This diagnostic support program is to raise the activation rate of the print circuit board under test in order to improve the diagnostic rate by a single diagnostic operation.

In a large scale electronic system device whose overall operation is controlled by a CPU, ordinarily, such an electronic system is loaded with a system diagnostic program. Such a system diagnostic program can detect malfunctions, errors, or defective parts of the large scale electronic system, but cannot specifically detect each defective location in a printed circuit board used in the system. Thus, by applying the present invention in diagnosing such a large scale electronic system, the efficiency in the test and repair of the electronic system will significantly improve because the present invention can specify the defective printed circuit board in the system and defective locations in the defective printed circuit board.

The first aspect of the present invention is a diagnostic apparatus for detecting failure points in a printed circuit board or an LSI which includes a controller unit such as a micro-processor unit (MPU) through a non-contact fashion. The diagnostic apparatus includes means for applying a test program to the controller unit to activate the electronic circuit network under test, a detector array formed with an insulator plane and a large number of detector electrodes for detecting and outputting voltage signals representing electric fields of various locations in the electronic circuit network under test, a measurement unit for converting each of the voltage signals from the detector array to a corresponding analog voltage representing a negative peak rate Mₚᵣ, a switch array for sequentially switching and outputting the analog voltage from the measurement unit, a processing unit for determining defective points in the circuit network under test based on measured data which is AD (analog-to-digital) converted from the analog voltage representing the negative peak rate Mₚᵣ from the switch array and supplemental information from a memory, and a display for displaying the defective points specified by the processing unit.

In the further aspect, preferably, the data bases having the supplemental information are configured by at least one data base showing information regarding non-defective electronic circuit network and a plurality of error data bases each being associated with negative peak rates for each node in the electronic circuit network under test when each node being in predetermined failure modes, the error data bases including information describing failure modes at each node in the electronic circuit network under test.

Preferably, the diagnostic support program is a simple repetitive program to provide periodical logic signals to all circuit components in the electronic circuit network under test without involving judgement or jump steps based on data from peripheral devices, thereby increasing an activation rate or an operation rate in the electronic circuit network under test.

The electronic circuit network under test is arranged by a test program from the diagnostic apparatus in such a way that a MPU (micro-processor unit) and a ROM (read only memory) form a pattern generator for generating test pattern for peripheral circuit components in the electronic circuit network under test as stimulus, wherein bidirectional buffers are provided between the pattern generator and the peripheral circuit components and direction buffers are provided between the pattern generator and bus lines in the electronic circuit network under test, thereby isolating the pattern generator from the peripheral circuit components.

A further aspect of the present invention is a diagnostic method for detecting failure points in a printed circuit board or an LSI which (electronic circuit network under test) having a controller unit such as a micro-processor unit (MPU) through a non-contact fashion. The diagnostic method is comprised of the following steps of producing a diagnostic support program for an electronic circuit network under test, installing the electronic circuit network under test to an diagnostic apparatus which is configured to measure negative peak rates at predetermined locations on the electronic circuit network under test, producing data bases having information regarding negative peak rates of a non-defective electronic circuit network under test and negative peak rates of a defective electronic circuit network under test and descriptions regarding failure modes, measuring negative peak rates of the electronic circuit network through the diagnostic apparatus to obtain measured data by running the diagnostic support program in the controller unit, retrieving the information in the data bases and comparing the measured data and the information in the data bases to determine a data base showing highest similarity to the measured data, and specifying defective points and failure modes based on the information in the data base showing the highest similarity to the measured data.

In the further aspect, the retrieving and comparing step is performed by the steps of comparing the measured data of negative peak rates corresponding to predetermined locations on the electronic circuit network under test with the data bases of non-defective electronic circuit network under test and the data bases of various failure modes, determining a number of differences between the measured data and the data base for each location of the electronic circuit network under test, accumulating the number of differences for all of the locations to obtain a total number of differences regarding each data base, and selecting the data base showing the smallest total number of differences and indicating failure mode information associated with the selected data base as a diagnostic result.

### BRIEF DESCRIPTION OF THE DRAWINGS

FIG. 1 is a block diagram showing an example of structure of the diagnostic apparatus of the present invention for diagnosing the electronic circuit network in a non-contact fashion.

FIG. 2 is a circuit diagram showing an example of electronic circuit network having a micro-processor unit for generating stimulus, thereby being appropriately diagnosed by the diagnostic apparatus of the present invention.

FIG. 3 is a flow diagram showing an example of operation in the diagnostic apparatus of the present invention.

FIG. 4 is a schematic diagram for explaining an example of operation in the diagnostic apparatus of the present invention using measured data and supplemental information in data bases.

FIG. 5 is a flow diagram showing an operation of the diagnostic apparatus and method of the present invention based on the relationship of FIG. 4.

FIG. 6 is a block diagram showing an example of structure in the diagnostic apparatus in the conventional technology.

FIG. 7 is a block diagram showing an example of structure in the negative peak rate measurement element in the diagnostic apparatus of FIG. 6.

### DETAILED DESCRIPTION OF THE PREFERRED EMBODIMENT

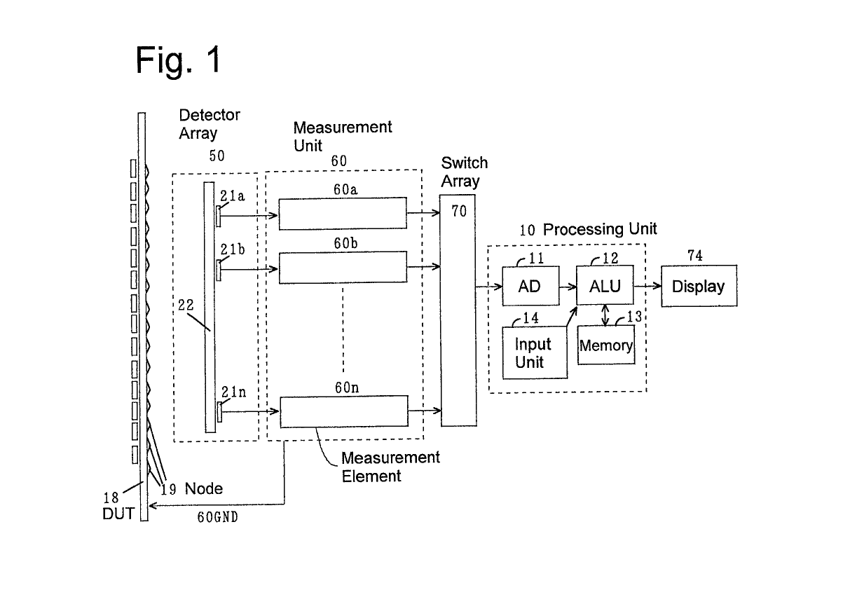

The embodiments of the present invention will be described with reference to the drawings. FIG. 1 shows an example of structure of the diagnosing apparatus of the present invention for diagnosing the electronic circuit network in a non-contact fashion.

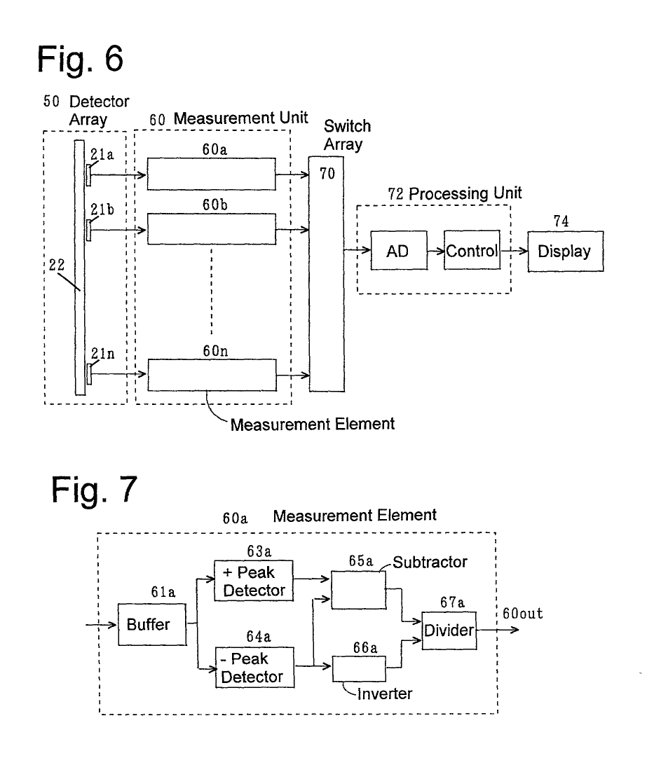

In FIG. 1, the diagnostic apparatus of the present invention is composed of a detector array 50, a measurement unit 60, a switch array 70, a processing unit 10, and a display 74. The detector array 50, the measurement unit 60, and the switch array 70 can be the same components as shown in the conventional apparatus of FIG. 6.

In the conventional example of FIG. 6, the processing unit 72 only controls the AD converter and the data displayed on the display screen 74. As shown in FIG. 1, however, the processing unit 10 used in the present invention includes an AD converter 11 for converting an analog signal to a digital signal, an arithmetic controller 12 which retrieves supplemental information from data bases formed in a memory 13 on the basis of output data from an AD converter 11, and a supplemental information supply (input) unit 14 for supplying supplemental information to the arithmetic controller 12. By the configuration of the processing unit 10, the diagnostic apparatus of the present invention can specify defective locations in the electronic circuit under test with high accuracy and high efficiency.

The AD converter 11 converts the analog voltage corresponding to each individual negative peak Mₚᵣ to digital data. The memory 13 forms data bases therein which store supplemental information of the electronic circuit network to be diagnosed. The supplemental information data base consists of more than one non-defective device data bases and a large number of error data bases correlating to the number of nodes in the electronic circuit network to be diagnosed. The non-defective device data base featuring supplemental information that gives specific indication (non-defective device A″ or “non-defective device D”. The error data bases include descriptions of specific failure modes for each node in the circuit such as “pin number 5 of IC 10 is short circuited to ground”. The supplemental information input unit 14 is a device that inputs the supplemental information to the memory 13 when forming the supplemental information data base.

The main operation of the arithmetic controller 12 is to check and search the information in the supplemental information data base stored in the memory 13 based on each measured data from the AD converter 11. The arithmetic controller 12 performs this function for all of the nodes of the electronic circuit network under test and determines whether the electronic circuit network under test is non-defective or defective, the result of which is displayed on the display screen 74. The details of this operation will be described later. Further function of the arithmetic controller 12 is to receive the supplemental information from the supplemental information input unit 14 for forming the supplemental information data bases in the memory 13.

Since the processing unit 10 includes the arithmetic controller 12 to achieve an arithmetic function, the arithmetic functions conducted by the subtractor 65a, inverter 66a, and divider 67a in the measurement unit 60a in FIG. 7 can also be conducted by the arithmetic unit 12 and the subtractor, inverter and divider can be deleted. Thus, the arithmetic controller 12 can be used to obtain the negative peak rates Mₚᵣ based on the positive peak voltage and the negative peak voltage from the measurement unit 60a.

The electronic circuit network suitable for being diagnosed by the apparatus of the present invention is an electronic circuit which is controlled by a CPU (central processor unit) or a MPU (micro-processor unit). In the present invention, by using a diagnostic support program, an entire circuit of the electronic circuit network under test is excited by periodical rectangular wave signals, thereby increasing the activation rate of the entire circuit. As a consequence, the entire operation of the circuit under test can be diagnosed by one diagnostic operation. Hence, it is necessary to install the diagnostic support program for each electronic circuit network under test through the MPU or CPU in the electronic circuit network.

An ordinary program involves many judgement steps and resultant jumps since the process is determined based data from peripheral devices. However, in the diagnostic support program, such steps of judgement and jump based on the data from the peripheral devices are not used. This is because, in the diagnostic apparatus of the present invention, it is necessary to minimize or avoid unexpected jumps in the operation of electronic circuit network under test by simplifying the operation of the MPU. Instructions without using the decision steps or jump steps can be used freely. Further, decision steps based on the MPU internal data without involving the data from peripheral devices, such as decision based on data showing an execution number of sub-routines is permissible. Thus, the MPU only conducts the writing operation for the peripheral devices.

The goal of the diagnostic support program is to activate all of the circuit components in the electronic circuit network under test, thereby making the negative peak rates Mₚᵣ constant. Thus, it is preferable that the diagnostic support program excites the electric circuit network under test so that the circuit components are activated by the same, simple periodical logic signals.

In the case where the MPU and a ROM (read only memory) in the electric circuit network form a pattern generator for generating diagnostic pattern for the circuit network, the operation of this pattern generator must be guaranteed. In other words, the operation of the pattern generator should not be affected by defective operations of the electric circuit network under test. If the operation of the pattern generator is affected by defective operations of peripheral components, accurate testing cannot be achieved. Thus, in such a situation, preferably, a buffer may be inserted in each signal line to isolate the pattern generator from the peripheral components.

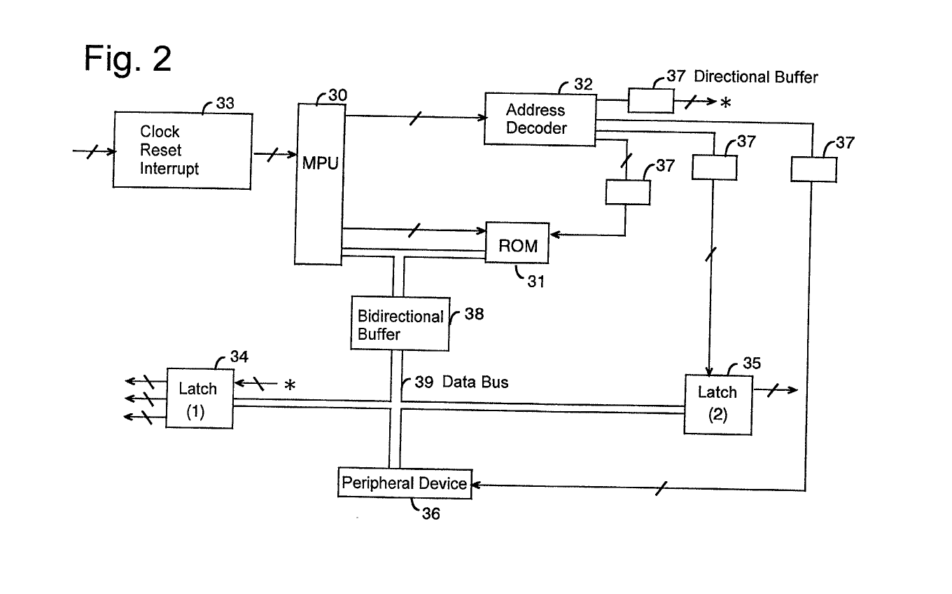

FIG. 2 shows an example of block diagram including components peripheral to the MPU in the electric circuit network suitable for being diagnosed by the diagnostic apparatus of the present invention. A pattern generator may be composed of a MPU 30, a ROM 31, and an address decoder 32 by installing a program for establishing the pattern generator. Between the pattern generator and peripheral devices 36, a bidirectional buffer 38 is inserted in a data bus 39, and directional buffers 37 are inserted in the address lines and control lines. This arrangement can effectively isolate the pattern generator from the surrounding components, such as peripheral devices 36 and latches 34 to guarantee the operation of the pattern generator.

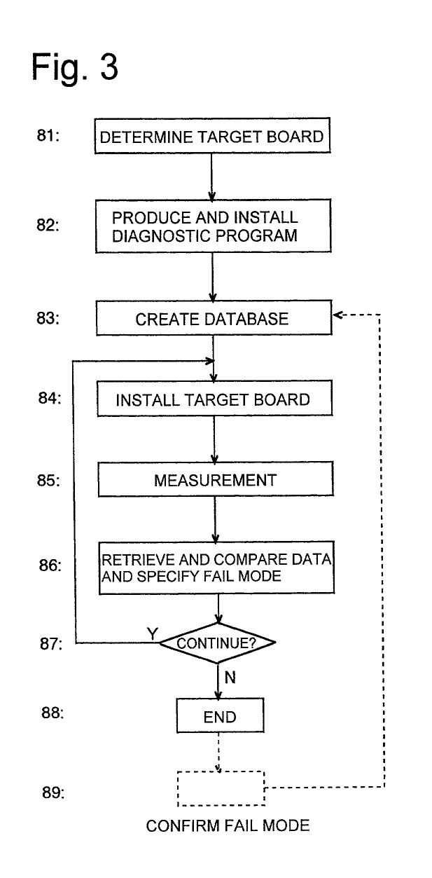

FIG. 3 shows an example of a procedural diagram involved in the diagnostic apparatus of the present invention. When the electronic circuit network to be diagnosed is specified (step 81), the diagnostic support program is produced and installed in the CPU of the diagnostic apparatus including MPU in the circuit network to be tested (step 82). Further, supplemental information data base regarding the circuit network to be diagnosed is created (step 83). As noted above, the diagnostic support program is a program to provide periodic signals to activate all of the components in the electric circuit network under test. If there is one that is already produced, such a diagnostic support program can be reused.

As previously explained, the supplemental information data base consists of data to be retrieved for comparing with each of the measured data describing the failure modes information of cause. The supplemental information data base is created in a manner described here. First, a non-defective electronic circuit network, such as a printed circuit board, is installed, and the diagnostic measurement is conducted, thereby acquiring data showing the non-defective circuit network. This data may be designated as “data of non-defective circuit A” in the data base through the supplemental information input unit 14.

The non-defective board is then used to deliberately make failure modes in order to acquire data indicating failure modes at each node. For example, there are two kinds of deliberately made failure modes (listed below) which will be created per nodes required on the printed circuit board. (1) An example of failure mode is created by short-circuiting a node to the ground GND through a resistor of low resistance value such as 10 ohms, and (2) another failure mode is created by short-circuiting a node with other node (such as two adjacent pins) through a resistor of low resistance value. If practical, other failure mode may be created such as by open-circuiting between nodes.

The larger number of data bases, the higher it becomes the diagnostic rate. For example, a printed circuit board of DIN A3 size has about 5,000-10,000 nodes. Therefore, in the case where data is acquired for the two failure modes for all of the nodes, the total number of the data bases will be 10,000-20,000. The supplemental information showing the failure mode such as “pin number 3 is short circuited to ground GND”, is stored in the data base at the same time.

The diagnostic operation is conducted. The printed circuit board to be tested is installed to the diagnosing apparatus of the present invention and the diagnostic measurement begins (step 84 and 85). The diagnostic apparatus retrieves the data based on the basis of the measured data to compare the similarity between the two (step 86). At the same time, the diagnostic apparatus retrieves the failure mode data (supplemental information) from the data base. This operation is repeated until all of the data bases are compared with the measured data (steps 87 and 88).

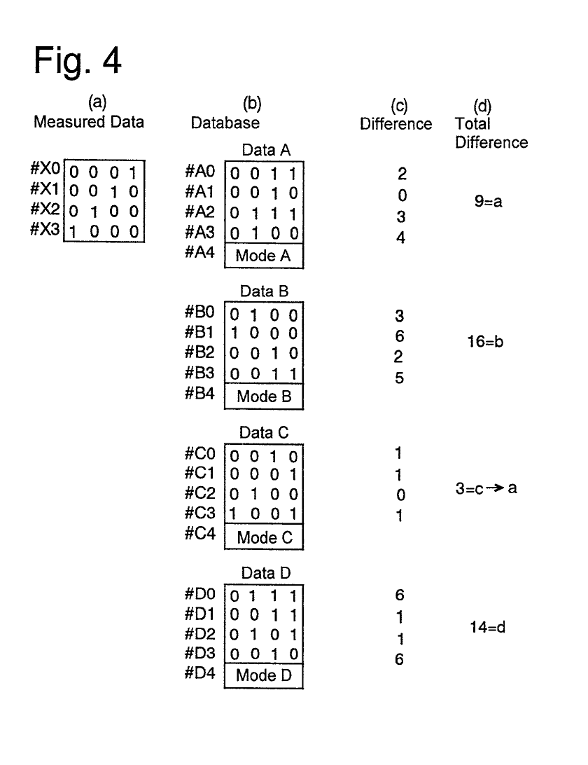

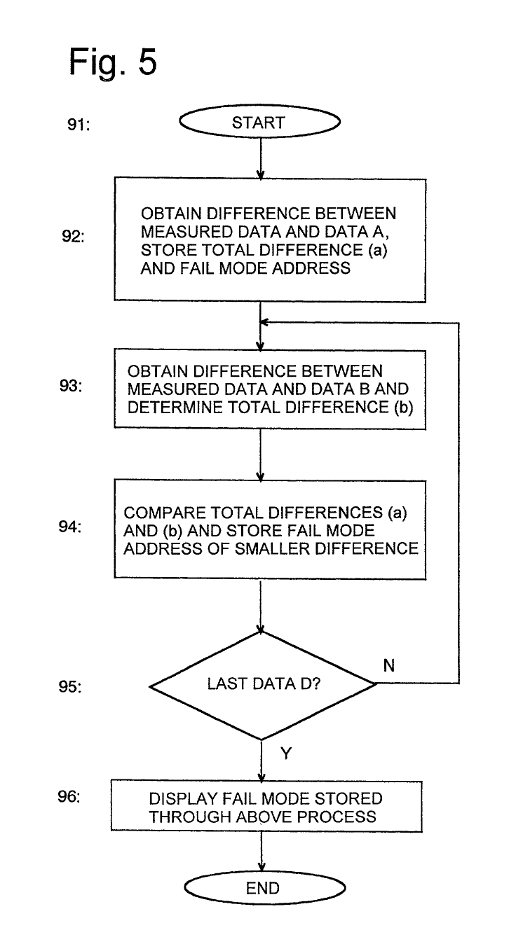

FIGS. 4(a)-4(d) are schematic diagrams for explaining an example of operation in the diagnostic apparatus of the present invention using measured data and supplemental information in the data base. This example shows the simplest case in which four bit measured data is derived from each of four detector electrodes and there are four data bases (supplemental information) corresponding to the measured data. FIG. 5 is a flow diagram showing the operation of the diagnostic apparatus corresponding to the example of FIG. 4.

FIG. 4(a) shows the measured data from the switch array 70 obtained through the detector electrodes X0-X3 and the measurement unit 60. Namely, in FIG. 4(a), the measured data indicating the negative peak rate corresponding to the detector electrode X0 is “0001”, and the measured data indicating the negative peak rate corresponding to the detector electrode X1 is “0010” and so on. Based on the measured data, the processing unit 10 retrieves the data base such as Data A-D from the memory 13 and compares the measured data and the data base such as “Data A” for each detector electrode X. As noted above, the data base is formed by the non-defective circuit board (for example “Data A”), the board having the deliberately created failure modes (for example “Data B”), and the board having another type of deliberately created failure modes (for example “Data C”), and so on. Further, the Data A-D include the description of failure modes Mode A-D, respectively, as shown in FIG. 4(b).

First, a difference between the measured data and the Data A is obtained which is temporarily stored in a memory. For example, with respect to the measured data “0001” (FIG. 4a) derived from detector electrode X0, the data A0 (in Data A) indicating “0011” is compared with the measured data. In this example, a difference “2” is obtained as shown in FIG. 4(c). Then the measured data “0010” corresponding to the detector electrode X1 is compared with the data A1 (in Data A), resulting in a difference “0”. In the present invention, the difference data between the measured data and data base A is accumulated in a manner shown in FIG. 4(d). The accumulated number of differences a=9 and the failure mode data “Mode A” is temporality stored in the memory.

Then the measured data of FIG. 4(a) is compared with the next data base (Data B) of FIG. 4(b) for each detector electrode in the manner described above. Each difference number is shown in FIG. 4(c), and the total number (accumulated number) of the differences b=16 is obtained in FIG. 4(d). Since the total number a=9 is smaller than the total number b=16, the total number a=9 is remain stored in the memory. By repeating this process for the remaining data base, it is known that the total number of difference c=3 with respect to the Data C is the smallest among the Data AD. This means that the data base “Data C” of FIG. 4(b) shows the highest similarity to the measured data of FIG. 4(a). In other words, the electronic circuit under test is in the same as or substantially similar condition to that described by the Data C. The supplemental information attached to the Data C, i.e., Mode C is also retrieved to show the failure mode (or non-defective) of the electric circuit under test.

FIG. 5 is a procedural diagram summarizing the operational process in the diagnostic apparatus of the present invention using the example of FIG. 4. The process starts at step 91 and compares the measured data and the data prepared in advance (Data A-D) with respect to each location (coordinated) on the electronic circuit under test. The process examines differences between the measured data and the selected data base (step 92). Further, the process accumulates the differences to obtain the total number of differences (step 93).

The total number of differences for the data base is compared with the total number of differences in the previous data base and the information regarding the data base having the smaller total number of differences is temporarily stored (step 94). In step 95, the process determines whether the all the data base are compared with the measured data, and if not, goes back to the step 93 to repeat the above steps until all of the data bases are compared with the measure data. When all of the data bases are used, the process displays the information in the data base which has the least number of differences from the measured data, i.e., the highest similarity to the circuit under test, and the failure mode associated with the data base.

During the time when the testing the printed circuit board, it is also possible that the measured data is temporarily stored and when the cause of failure (failure mode) is confirmed, the measured data is added to the supplemental information. Then, the supplemental information is renewed with the information of higher accuracy, and the amount of information in the data base will be increased, resulting in increase in the diagnostic rate.

As explained in detail, in the conventional diagnostic apparatus, the activation rate (rate of operational in circuit components) in an electronic circuit network under test, such as a printed circuit board is lass than 50%. Therefore, a diagnostic rate better than 50% could not be achieved. Furthermore, the diagnostic results can only specify an area having groups of points or nodes instead of specifying point by point, and a separate operation is required to specify the failure points.

In the present invention, however, since the entire circuit components in the electronic circuit network under test are activated by the diagnostic support program, the diagnostic measurement can be stabilized, and the diagnostic rate can be increased.

Further, each of the failure points or nodes and the failure mode thereof in the circuit network under test can be specified with use of the data bases having supplemental information regarding the non-defective circuit network and data associated with various failure modes. By comparing the measured data and the information in the data bases and choosing the data base showing the highest similarity to the measured data, the locations and failure modes of the defective points in the circuit network under test can be specified, which makes it possible to efficiently carry out the repair work and the design change in the electronic circuit network.

The diagnostic performance can be further improved by adding the information obtained in repairing the defective points detected by the diagnostic apparatus to the supplemental information in the data bases.

Although only a preferred embodiment is specifically illustrated and described herein, it will be appreciated that many modifications and variations of the present invention are possible in light of the above teachings and within the purview of the appended claims without departing the spirit and intended scope of the invention.

What is claimed is:

1. An electronic circuit diagnostic apparatus for detecting failure points in a printed circuit board or an LSI which (electronic circuit network under test) includes a controller unit such as a micro-processor unit (MPU) through a non-contact fashion, comprising:
means for applying a diagnostic support program to the controller unit to activate the electronic circuit network under test;
a detector array formed with an insulator plane and a large number of detector electrodes for detecting and outputting voltage signals representing electric fields of various locations in the electronic circuit network under test;
a measurement unit for converting each of the voltage signals from the detector array to a corresponding analog voltage representing a negative peak rate Mₚᵣ;
a switch array for sequentially switching and outputting the analog voltage from the measurement unit;
a processing unit for determining defective points in the electronic circuit network under test based on measured data which is AD (analog-to-digital) converted data of the analog voltage representing the negative peak rate Mₚᵣ from the switch array and supplemental information in data bases from a memory; and
a display for displaying the defective points specified by the processing unit.

2. An electronic circuit diagnostic apparatus as defined in claim 1, wherein the data bases having the supplemental information are configured by at least one data base showing information regarding non-defective electronic circuit network and a plurality of error data bases each being associated with negative peak rates for each node in the electronic circuit network under test when each node being in predetermined failure modes, the error data bases including information describing failure modes at each node in the electronic circuit network under test.

3. An electronic circuit diagnostic apparatus as defined in claim 1, wherein the diagnostic support program is a simple repetitive program to provide periodical logic signals to all circuit components in the electronic circuit network under test without involving judgement or jump steps based on data from peripheral devices, thereby increasing an activation rate or an operation rate in the electronic circuit network under test.

4. An electronic circuit diagnostic apparatus as defined in claim 1, wherein the electronic circuit network under test is arranged by a test program from the diagnostic apparatus in such a way that a MPU (micro-processor unit) and a ROM (read only memory) form a pattern generator for generating test pattern for peripheral circuit components in the electronic circuit network under test as stimulus, wherein bidirectional buffers are provided between the pattern generator and the peripheral circuit components and direction buffers are provided between the pattern generator and bus lines in the electronic circuit network under test, thereby isolating the pattern generator from the peripheral circuit components.

5. A diagnostic method for detecting failure points in a printed circuit board or an LSI which (electronic circuit network under test) having a controller unit such as a micro-processor unit (MPU) through a non-contact fashion, comprising the following steps of;
producing a diagnostic support program for an electronic circuit network under test;
installing the electronic circuit network under test to an diagnostic apparatus which is configured to measure negative peak rates at predetermined locations on the electronic circuit network under test;
producing data bases having information regarding negative peak rates of a non-defective electronic circuit network under test and negative peak rates of a defective electronic circuit network under test and descriptions regarding failure modes;
measuring negative peak rates of the electronic circuit network through the diagnostic apparatus to obtain measured data by running the diagnostic support program in the controller unit;
retrieving the information in the data bases and comparing the measured data and the information in the data bases to determine a data base showing highest similarity to the measured data; and
specifying defective points and failure modes based on the information in the data base showing the highest similarity to the measured data.

6. A diagnostic method as defined in claims 5, the retrieving and comparing step is performed by the steps of:
comparing the measured data of negative peak rates corresponding to predetermined locations on the electronic circuit network under test with the data bases of non-defective electronic circuit network under test and the data bases of various failure modes;
determining a number of differences between the measured data and the data base for each location of the electronic circuit network under test;
accumulating the number of differences for all of the locations to obtain a total number of differences regarding each data base; and
selecting the data base showing the smallest total number of differences and indicating failure mode information associated with the selected data base as a diagnostic result.
